(19) United States
(12) Patent Application Publication
(10) Pub. No.: US 2023/0403918 A1
(43) Pub. Date: Dec. 14, 2023

(54) METHOD FOR PRODUCING VERTICAL ORGANIC LIGHT-EMITTING TRANSISTOR DEVICE, DISPLAY

(71) Applicants: JSR CORPORATION, Tokyo (JP); Mattrix Technologies, Inc, Gainesville, FL (US)

(72) Inventors: Hiromitsu Katsui, Minato-ku (JP); Bo Liu, Gainesville, FL (US); Maxime Lemaitre, Gainesville, FL (US); Hiroyuki YASUDA, Minato-ku (JP)

(21) Appl. No.: 17/836,389

(22) Filed: Jun. 9, 2022

(51) Int. Cl. H01L 51/56; H01L 51/00; H01L 51/52

(52) U.S. Cl. CPC H01L 51/56; H01L 51/0021; H01L 51/5296; H01L 51/0048

(57) ABSTRACT

The method for producing a vertical organic light-emitting transistor device includes: a step (A) in which a substrate having a main surface, on which the vertical organic light-emitting transistor device is to be formed, is prepared; a step (B) in which an organic material containing a polymer having a hydrocarbon group is applied onto the main surface of the substrate; a step (C) in which a dispersion liquid containing a dispersant and a carbon material is applied onto an organic material layer formed in the step (B); a step (D) in which a coating film formed in the step (C) is dried; and a step (E) in which after the step (D) is performed, a cleaning fluid is applied to remove the dispersant.

### BACKGROUND OF THE INVENTION

### Field of the Invention

The present invention relates to a method for producing a light-emitting device, and particularly relates to a method for producing a vertical organic light-emitting transistor device. The present invention also relates to a display.

### Description of the Related Art

A light-emitting transistor is known which uses a nano-carbon material for an electrode. For example, Patent Document 1 mentioned below discloses a vertical organic light-emitting transistor device using a nano-carbon material for a source electrode. Such a technique makes it possible to eliminate the need for an additional driving horizontal transistor unlike a conventional light-emitting diode and to significantly reduce a channel length as compared to a lateral transistor having a channel formed in parallel with a semiconductor layer surface because a channel is formed in the thickness direction of a semiconductor layer. This makes it possible to efficiently pass an electric current having a desired magnitude through the light-emitting transistor.

### PRIOR ART DOCUMENTS

### Patent Documents

Patent Document 1: Japanese Patent No. 6272030
Patent Document 2: WO2021/033482
Patent Document 3: JP-A-2016-118763

### SUMMARY OF THE INVENTION

When an electrically conductive layer is not evenly formed on a substrate in a semiconductor light-emitting device such as a light-emitting diode or a light-emitting transistor, a current density is unevenly distributed in the semiconductor light-emitting device so that high-brightness areas and low-brightness areas are formed in each pixel. Further, there is a possibility that brightness varies from pixel to pixel in the entire display area. Particularly, brightness unevenness that can be recognized by humans relates to the quality of a display, and therefore it is desirable that an electrically conductive layer formed as part of the semiconductor light-emitting device is formed evenly on the substrate. Further, an electrically conductive layer formed particularly in a vertical organic light-emitting transistor device needs to be thin and its area needs to be mostly a void because transistor operation is performed by an electric field generated by a gate electrode of the light-emitting transistor.

An electrically conductive layer made of a nano-carbon material used in a semiconductor device is formed by applying, onto a substrate, a dispersion liquid prepared by mixing a nano-carbon material with a predetermined dispersant and performing drying treatment, baking treatment, and then cleaning treatment to remove the dispersant.

However, when an electrically conductive layer is formed simply by applying a dispersant mixed with a nano-carbon material onto a substrate and performing predetermined treatment, in most cases, the electrically conductive layer formed on the substrate may unevenly be distributed without being evenly spread. Particularly, in the process of forming an electrically conductive layer required of a vertical organic light-emitting transistor device, which is thin and whose area is mostly a void, uneven distribution of an electrically conductive material is likely to occur, and therefore there is a high possibility that a problem arises. For this reason, a semiconductor light-emitting device having an electrically conductive layer made of a nano-carbon material may cause brightness unevenness, and therefore has not actively been used for displays from the viewpoints of quality and reliability.

In view of the above problem, it is an object of the present invention to provide a method for producing a vertical organic light-emitting transistor device, which makes it possible to evenly fix a nano-carbon material to the entire area onto which a dispersant is applied.

In order to achieve the above object, the present invention is directed to a method for producing a vertical organic light-emitting transistor device, including:
a step (A) in which a substrate having a main surface, on which the vertical organic light-emitting transistor device is to be formed, is prepared;
a step (B) in which an organic material containing a polymer having a hydrocarbon group is applied onto the main surface of the substrate:
a step (C) in which a dispersion liquid containing a dispersant and a carbon material is applied onto an organic material layer formed in the step (B);
a step (D) in which a coating film formed in the step (C) is dried; and
a step (E) in which after the step (D) is performed, a cleaning fluid is applied to remove the dispersant.

In the production method, the dispersion liquid may contain the dispersant in an amount of 1,000% by mass to 100,000% by mass with respect to an amount of the carbon material.

In the production method, the carbon material may be at least one selected from among a carbon nanotube, graphene, and fullerene. It is to be noted that the nano-carbon material is preferably a carbon nanotube.

In the production method, the dispersant may be a polymer having a moiety represented by the following chemical formula (1), and the dispersion liquid may be an organic solvent.

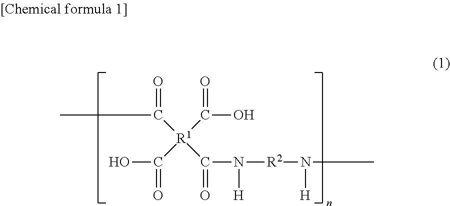

(wherein R¹ is a tetravalent organic group constituting a tetracarboxylic acid, R² is a divalent organic group constituting a diamine, and n is a positive integer.)

In the production method, R¹ in the moiety of the dispersant represented by the above chemical formula (1) may be a cyclobutane ring.

In the production method, the dispersant may have an acid-dissociable group.

In the production method, the organic material containing a polymer having a hydrocarbon group may have an oxygen content of 1% by mass or less.

In the above production method, the step (C) may be performed by applying the dispersion liquid onto the organic material layer by any one of application methods including spin coating, slit coating, bar coating, spray coating, and ink-jet coating.

In the above production method, the cleaning fluid may be an alkaline aqueous solution.

The present invention is also directed to a display including a vertical organic light-emitting transistor device produced by the above production method.

It is to be noted that other aspects of the present invention will become apparent from the following description and drawings.

According to the present invention, it is possible to achieve a method for producing a vertical organic light-emitting transistor device, which makes it possible to evenly fix a nano-carbon material to the entire area onto which a dispersant is applied.

### BRIEF DESCRIPTION OF THE DRAWINGS

FIG. 1 is a schematic diagram showing the overall structure of a display of an embodiment;

FIG. 2 is a diagram showing the circuit structure of a pixel of the display of the embodiment;

FIG. 3 is a top view of one of pixels of the display of the embodiment;

FIG. 4 is a cross-sectional view of the pixel taken along a line A-A′ shown in FIG. 3;

FIG. 5 is a top view showing the process of producing a light-emitting transistor of the embodiment;

FIG. 6 is a top view showing the process of producing the light-emitting transistor of the embodiment;

FIG. 7 is a top view showing the process of producing the light-emitting transistor of the embodiment;

FIG. 8 is a top view showing the process of producing the light-emitting transistor of the embodiment;

FIG. 9 is a top view showing the process of producing the light-emitting transistor of the embodiment;

FIG. 10 is a top view showing the process of producing the light-emitting transistor of the embodiment;

FIG. 11 is an AFM photograph of the surface of a substrate; and

FIG. 12 is an AFM photograph of the surface of a substrate.

### DETAILED DESCRIPTION OF THE PREFERRED EMBODIMENTS

Hereinbelow, the structure of a display 1 having a vertical organic light-emitting transistor device as an embodiment will first be described, and then an embodiment of a method for producing the display 1 according to the present invention will be described in detail. Then, a verification and evaluation experiment will finally be described in detail which was performed by an example of a method for producing a vertical organic light-emitting transistor device according to the present invention to verify the effects of the present invention.

### [Overall Structure]

The overall structure of the display 1 of the present embodiment will be described. FIG. 1 is a schematic diagram showing the overall structure of the display 1 of the present embodiment. The display 1 includes a substrate 2. On one surface of the substrate 2, a display area 2a and a peripheral area 2b are provided.

The substrate 2 is a material having translucency. Examples of such a material include a glass substrate, a quartz substrate, and an organic resin substrate. Examples of the material of the organic resin substrate include a polyimide and the like. The organic resin substrate can have a thickness of several micrometers to several tens of micrometers, which makes it possible to achieve a flexible sheet display.

The display area 2a is an area to display an image. In the present embodiment, a plurality of pixels 3 are arranged in a matrix in the display area 2a. Further, in the display area 2a, a scan signal line 34 is provided for each pixel row, and a video signal line 35 and a power source potential line 36 are provided for each pixel column. Although not shown in FIG. 1, a common potential line 37 that will be described later is provided across the pixels 3.

The peripheral area 2b is an area outside the display area 2a. In the peripheral area 2b, a driving circuit 4, an LSI chip 5, and a terminal part 6 are provided. The driving circuit 4 is a circuit for driving the pixels 3 arranged in the display area 2a. The driving circuit 4 incudes a scan line driving circuit and a video line driving circuit that are not shown in the drawings. The LSI chip 5 controls the driving circuit 4. The terminal part 6 is provided to connect the display 1 to an external terminal such as a FPC (Flexible Printed Circuit).

### (Pixel Circuit)

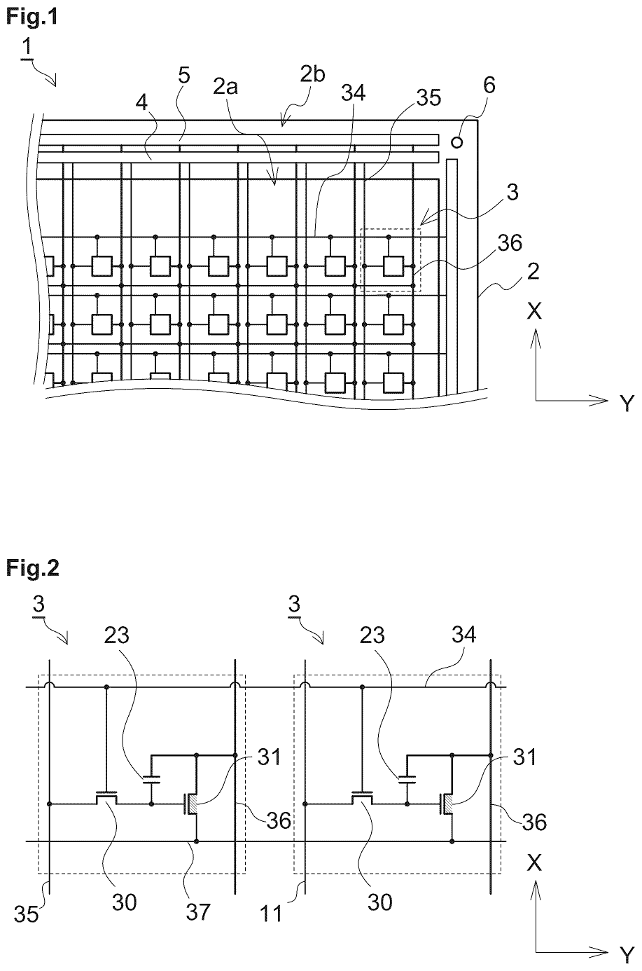

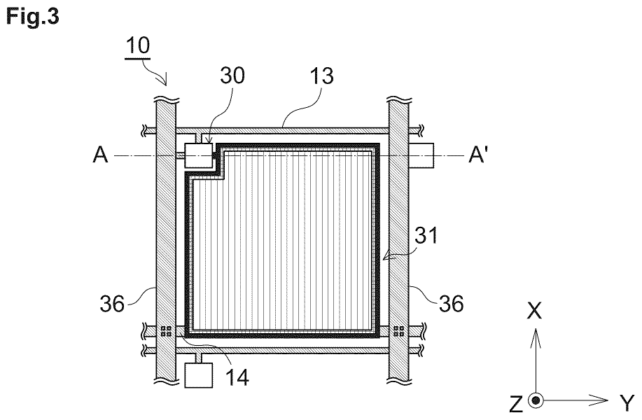

FIG. 2 is a diagram for explaining the circuit structure of each of the pixels 3 of the present embodiment. Each of the pixels 3 has a select transistor 30 and a light-emitting transistor 31.

The select transistor 30 controls electrical conduction between the video signal line 35 and agate electrode 311 of the light-emitting transistor 31 by on-off operation. A source electrode 301 of the select transistor 30 is connected to the video signal line 35. A drain electrode 302 of the select transistor 30 is connected to the gate electrode 311 of the light-emitting transistor 31 (see FIG. 3). A gate electrode 300 of the select transistor 30 is connected to the scan signal line 34.

The light-emitting transistor 31 emits light whose brightness depends on a voltage applied to the gate electrode 311. A source electrode 314 of the light-emitting transistor 31 is connected to the power source potential line 36. A drain electrode 316 of the light-emitting transistor 31 is connected to the common potential line 37. The gate electrode 311 of the light-emitting transistor 31 is connected to the drain electrode 302 of the select transistor 30.

### (Drive Control)

A predetermined power source potential is applied to the source electrode 314 of the light-emitting transistor 31 through the power source potential line 36. Further, a predetermined common potential is applied to the drain electrode 316 of the light-emitting transistor 31 through the common potential line 37. That is, a predetermined constant voltage is applied between the source and drain electrodes (314, 316) of the light-emitting transistor 31. When a voltage is applied to the gate electrode 311 of the light-emitting transistor 31, an electric field from the gate electrode 311 is controlled, and an electric current between the source and drain electrodes (314, 316) is controlled.

The scan line driving circuit selects each of the rows of the pixels 3 in order on the basis of a timing signal input from the LSI chip 5. At this time, the scan line driving circuit applies, to the scan signal line 34 connected to the pixels 3 of the pixel row, a voltage to turn on the select transistors 30.

The video line driving circuit receives a video signal from the LSI chip 5 and applies, to each of the video signal lines 35, a voltage depending on the video signal of the selected row of the pixels 3 on the basis of the selection of the scan signal line 34 by the scan line driving circuit. The voltage is applied to the gate electrode 311 of the light-emitting transistor 31 at the selected pixel row. As a result, an electric current depending on the voltage applied to the gate electrode 311 is supplied to a light-emitting layer 315 between the source and drain electrodes (314, 316) of the light-emitting transistor 31. In this way, the light-emitting transistor 31 connected to the selected scan signal line 34 emits light at a brightness depending on the electric current.

### (Pixel Structure)

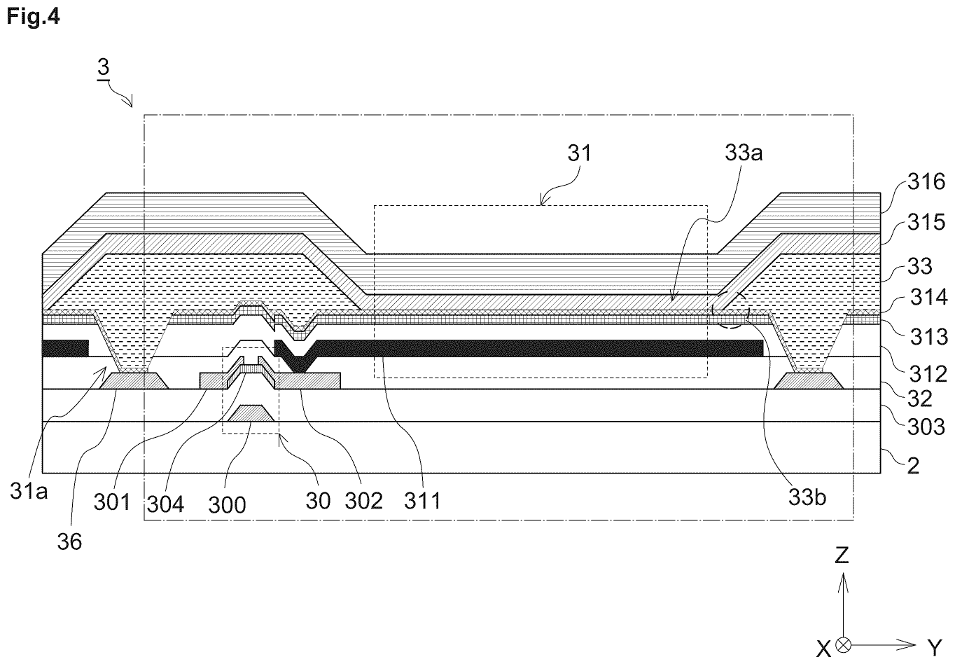

FIG. 3 is a top view of one of the pixels 3 of the display 1 of the present embodiment. FIG. 4 is a cross-sectional view of the pixel taken along a line A-A′ shown in FIG. 3. The display 1 of the present embodiment is a so-called bottom emission-type display 1 in which light emitted from the light-emitting transistor 31 is extracted from the substrate 2 side. Each of the pixels 3 of the present embodiment includes the select transistor 30, the light-emitting transistor 31, a protective layer 32, and a bank 33.

The select transistor 30 includes the gate electrode 300, the source electrode 301, the drain electrode 302, a gate insulating layer 303, and a semiconductor layer 304. The select transistor 30 of the present embodiment has a so-called bottom gate top contact (BGTC) structure in which the gate electrode 300, the gate insulating layer 303, the semiconductor layer 304, and the source and drain electrodes (301, 302) are provided in this order from the substrate 2 side.

It is to be noted that the structure of the select transistor 30 is not limited to the BGTC structure, and may be a bottom gate bottom contact (BGBC) structure, a top gate bottom contact (TGBC) structure, or a top gate top contact (TGTC) structure.

As a material of the semiconductor layer 304 of the select transistor 30, a silicon-based semiconductor, an oxide-based semiconductor, an organic semiconductor, or the like can be used.

The protective layer 32 is provided to cover and protect the select transistor 30 and plays the role of electrically insulating the source electrode 301 and the drain electrode 302 from electrodes provided as upper layers. As a material of the protective layer 32, an inorganic insulating material can be used. Examples of the inorganic insulating material include silicon nitride, silicon oxide, aluminum nitride, and aluminum oxide. The protective layer 32 is provided over the entire surface of the substrate 2. By providing the protective layer 32, the select transistor 30 and the power source potential line 36 are covered with the protective layer 32.

As shown in FIG. 3, an area constituting one pixel is mostly occupied by the light-emitting transistor 31, and the select transistor 30 is provided as small as possible at a corner of the area constituting one pixel. Further, in the cross-sectional view shown in FIG. 4, the light-emitting transistor 31 is provided over the protective layer 32.

The light-emitting transistor 31 includes the gate electrode 311, a gate insulating layer 312, a base layer 313, the source electrode 314, the light-emitting layer 315, and the drain electrode 316.

The gate electrode 311 is provided over the protective layer 32. In one pixel, the gate electrode 311 is provided outside an area occupied by the select transistor 30. Further, the gate electrode 311 is connected to the drain electrode 302 of the select transistor 30 through a contact hole 32a provided in the protective layer 32.

As a material of the gate electrode 311, a material having translucency and electrical conductivity is used to transmit light emitted from the light-emitting layer 315 to the substrate 2 side. Specifically, ITO (indium tin oxide), IZO (indium zinc oxide), or the like can be used as a material of the gate electrode 311. Alternatively, a metallic material having a thickness that can transmit light may be used as a material of the gate electrode 311.

The gate insulating layer 312 is provided on the upper side of the gate electrode 311. The gate insulating layer 312 is provided over the entire surface of the substrate 2. As a material of the gate insulating layer 312, the same material as the gate insulating layer 303 of the select transistor 30 can be used.

The base layer 313 is provided over the gate insulating layer 312. The base layer 313 has an opening 313a. The opening 313a is provided over the power source potential line 36. The base layer 313 is made of a dielectric material. Alternatively, the base layer 313 may be made of a material having radiation sensitivity and photosensitivity. The material of the base layer 313 is an organic material containing an aromatic compound, and examples of such an organic material that can be used include an aromatic polymer, a radiation-sensitive composition containing a polymer such as a polyimide and a photosensitizing agent, a polymer containing a cinnamic acid group, and a fluorine-based polymer having a cross-linkable group. It is to be noted that the organic material used in the present embodiment has an oxygen content of 1% by mass or less, but the oxygen content of the organic material may be 1% or more.

The source electrode 314 is provided on and in contact with the base layer 313. The source electrode 314 is connected through the opening 313a of the base layer 313 to the power source potential line 36 provided under the base layer 313.

The material of the source electrode 314 is a material containing a nano-carbon material. The nano-carbon material is graphene, fullerene, or a carbon nanotube, and the material of the source electrode 314 contains at least one of them. The nano-carbon material is preferably a carbon nanotube. As the carbon nanotube, a single-wall carbon nanotube or a double- or multi-wall carbon nanotube can be used. The nano-carbon material is preferably a single-wall carbon nanotube. Hereinafter, the carbon nanotube is sometimes abbreviated as “CNT”.

The source electrode 314 is formed by applying a dispersion liquid containing a nano-carbon material such as a carbon nanotube and a dispersant. The dispersant is not particularly limited, but a polyamic acid having a moiety represented by the chemical formula (1) is preferably used from the viewpoint of improving the dispersibility of the carbon nanotube. For confirmation, the chemical formula (1) is again shown.

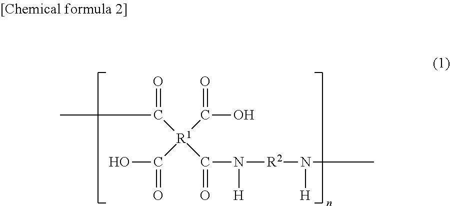

(wherein R¹ is a tetravalent organic group constituting a tetracarboxylic acid, R² is a divalent organic group constituting a diamine, and n is a positive integer.)

Specific examples of the tetravalent organic group represented by R¹ and constituting a tetracarboxylic acid include: dianhydrides of aromatic tetracarboxylic acids such as pyromellitic acid, 2,3,6,7-naphthalenetetracarboxylic acid, 1,2,5,6-naphthalenetetracarboxylic acid, 1,4,5,8-naphthalenetetracarboxylic acid, 2,3,6,7-anthracenetetracarboxylic acid, 1,2,5,6-anthracenetetracarboxylic acid, 3,3′,4,4′-biphenyltetracarboxylic acid, 2,3,3′,4-biphenyltetracarboxylic acid, bis(3,4-dicarboxyphenyl) ether, 3,3′,4,4′-benzophenonetetracarboxylic acid, bis(3,4-dicarboxyphenyl)sulfone, bis(3,4-dicarboxyphenyl)methane, 2,2-bis(3,4-dicarboxyphenyl)propane, 1,1,1,3,3,3-hexafluoro-2,2-bis(3,4-dicarboxyphenyl)propane, bis(3,4-dicarboxyphenyl)dimethylsilane, bis(3,4-dicarboxyphenyl)diphenylsilane, 2,3,4,5-pyridinetetracarboxylic acid, and 2,6-bis(3,4-dicarboxyphenyl)pyridine; dianhydrides of tetracarboxylic acids having an alicyclic structure, such as 1,2,3,4-cyclobutanetetracarboxylic acid, 1,2,3,4-cyclopentanetetracarboxylic acid, 1,2,4,5-cyclohexanetetracarboxylic acid, 2,3,5-tricarboxycyclopentylacetic acid, and 3,4-dicarboxy-1,2,3,4-tetrahydro-1-naphthalenesuccinic acid; and dianhydrides of aliphatic tetracarboxylic acids such as 1,2,3,4-butanetetracarboxylic acid and the like. These acid dianhydrides as compounds may be used singly or in combination of two or more of them.

Specific examples of the divalent organic group represented by R² and constituting a diamine include: aromatic diamines such as p-phenylenediamine, m-phenylenediamine, 2,5-diaminotoluene, 2,6-diaminotoluene, 4,4′-diaminobiphenyl, 3,3′-dimethyl-4,4′-diaminobiphenyl, 3,3′-dimethoxy-4,4′-diaminobiphenyl, diaminodiphenylmethane, diamino diphenyl ether, 2,2′-diaminodiphenylpropane, bis(3,5-diethyl-4-aminophenyl)methane, diaminodiphenylsulfone, diaminobenzophenone, diaminonaphthalene, 1,4-bis(4-aminophenoxy)benzene, 1,4-bis(4-aminophenyl)benzene, 9,10-bis(4-aminophenyl)anthracene, 1,3-bis(4-aminophenoxy)benzene, 4,4′-bis(4-aminophenoxy)diphenylsulfone, 2,2-bis[4-(4-aminophenoxy)phenyl]propane, 2,2-bis(4-aminophenyl)hexafluoropropane, and 2,2-bis[4-(4-aminophenoxy)phenyl]hexafluoropropane; alicyclic diamines such as bis(4-aminocyclohexyl)methane, bis(4-amino-3-methylcyclohexyl)methane, and 3,5-diaminobenzoic acid cholestanyl; aliphatic diamines such as 1,2-diaminoethane, 1,3-diaminopropane, 1,4-diaminobutane, and 1,6-diaminohexane; and silicondiamines such as 1,3-bis(3-aminopropyl)-1,1,3,3-tetramethyldisiloxane and the like. These diamines as compounds may be used singly or in combination of two or more of them.

Further, the R¹ in the above chemical formula (1) is preferably a cyclobutane ring from the viewpoint that the ring structure of a cyclobutane ring is decomposed by light irradiation or heating so that the structure of the polyamic acid is changed, which makes it easy to remove the dispersant. Further, the dispersant may contain an organic solvent as a dispersion medium.

The light-emitting layer 315 is a layer containing an organic electroluminescent (organic EL) material. The light-emitting layer 315 is provided over the source electrode 314. The light-emitting layer 315 is provided so as to cover the rim of an opening 33a of the bank 33 that will be described later and its vicinity. When electrons and holes are injected to the light-emitting layer 315 from the source electrode 314 and the drain electrode 316, respectively, the electrons and the holes are recombined. Excess energy discharged by this excites luminescent molecules in the light-emitting layer 315, and then light emission occurs due to deexcitation. The light-emitting layer 315 may include a hole transport layer and an electron transport layer and the like so that an organic EL material layer is sandwiched between them.

The drain electrode 316 is provided over the light-emitting layer 315. The drain electrode 316 corresponds to the area of part of the common potential line 37 shown in FIG. 2. The pixels 3 have the common potential line 37 in common, and all the common potential lines 37 are electrically connected.

The material of the drain electrode 316 preferably contains a metallic material having a high reflectance to reflect light emitted from the light-emitting layer 315 toward the substrate 2 side. As such a metallic material having a high reflectance, for example, aluminum, silver, or the like can be used.

The bank 33 is provided over the base layer 313 and the source electrode 314. The bank 33 has the opening 33a, and when viewed from above, the bank 33 is provided so that a rim 33b of the opening 33a covers the periphery of the source electrode 314 and its vicinity. The material of the bank 33 is an insulating material. As the insulating material, an inorganic insulating material, an organic insulating material, or a combination thereof can be used. By providing the bank 33, short circuit between the source electrode 314 and the drain electrode 316 can be prevented.

Although not shown, a protective layer may be provided over the drain electrode 316 so as to cover the entire surface of the substrate 2. The protective layer prevents deterioration of the properties of the light-emitting transistor 31 caused by entry of moisture into the light-emitting laver 315. As a material of the protective layer, an inorganic insulating material can be used. Examples of the inorganic insulating material include silicon nitride, silicon oxide, aluminum nitride, aluminum oxide, and a laminate of a combination of any two or more of these materials. It is to be noted that the protective layer is not provided at the positions of the LSI chip 5 and the terminal part 6 in order to make an electrical connection to an external terminal.

### [Production Method]

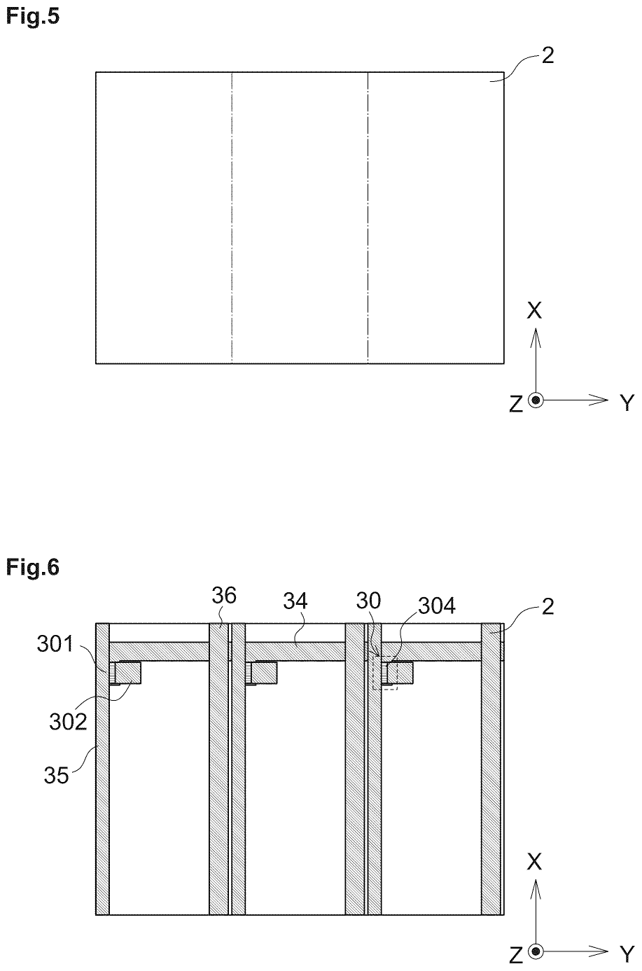

A method for producing the light-emitting transistor 31 of the present embodiment, especially a method for producing the pixels 3 of the display 1, will be described. FIGS. 5 to 12 are each a top view showing the production process of the light-emitting transistors 31 of the present embodiment.

First, as shown in FIG. 5, a substrate 2 is prepared which has a main surface on which light-emitting transistors 31 are to be formed (corresponding to the step (A)).

Then, as shown in FIG. 6, select transistors 30 are formed in portions on one surface side of the substrate 2. The select transistors 30 are formed through a process in which each of a gate electrode 300, a gate insulating layer 303, a semiconductor layer 304, and source and drain electrodes (301, 302) is formed by film formation using its material, resist application, exposure, development, and etching. The select transistors 30 can be produced by a general method, and therefore a detailed description about a method for producing the select transistors 30 will be omitted here.

It is to be noted that in the present embodiment, as shown in FIG. 6, power source potential lines 36 are formed at the same time as the formation of the source and drain electrodes (301, 302) in the step of forming the select transistors 30.

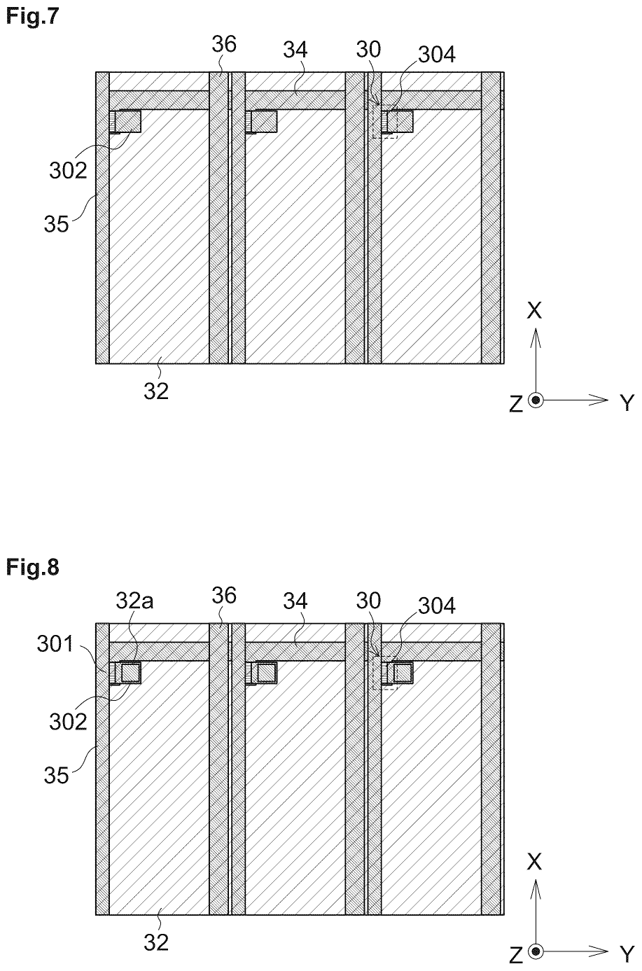

Then, as shown in FIG. 7, a protective layer 32 is formed. As a material of the protective layer 32, an inorganic insulating material is used. Examples of the inorganic insulating material include silicon nitride, silicon oxide, aluminum nitride, and aluminum oxide. The protective layer 32 is formed using a film formation method such as chemical vapor deposition or sputtering. The protective layer 32 is formed over the entire surface of the substrate 2. By forming the protective layer 32, the select transistors 30 and the power source potential lines 36 are covered with the protective layer 32.

After the protective layer 32 is formed, as shown in FIG. 8, contact holes 32a are formed in areas of the protective layer 32 located over the drain electrodes 302. The contact holes 32a are formed to connect gate electrodes 311 of light-emitting transistors 31 and the drain electrodes 302 of the select transistors 30.

Then, light-emitting transistors 31 are formed. First, as shown in FIG. 9, gate electrodes 311 are formed on the protective layer 32. The gate electrodes 311 are formed also on the contact holes 32a formed by the protective layer 32 to be connected to the drain electrodes 302 of the select transistors 30.

As a material of the gate electrodes 311, a material having translucency and electrical conductivity is used. Specifically. ITO (indium tin oxide), IZO (indium zinc oxide), or the like can be used as a material of the gate electrodes 311. Alternatively, a metallic material having a thickness that can transmit light may be used as a material of the gate electrodes 311. The gate electrodes 311 are formed by forming a film from their material by sputtering or the like and then removing an unnecessary portion by etching.

After the gate electrodes 311 are formed, as shown in FIG. 4, a gate insulating layer 312 is formed. It is to be noted that the gate insulating layer 312 is formed over the entire surface of the substrate 2, and therefore how to form the gate insulating layer 312 is not diagrammatically shown.

As a material of the gate insulating layer 312, the same material as the gate insulating layer 303 of the select transistors 30 can be used. The gate insulating layer 312 is formed using a film formation method such as chemical vapor deposition or sputtering.

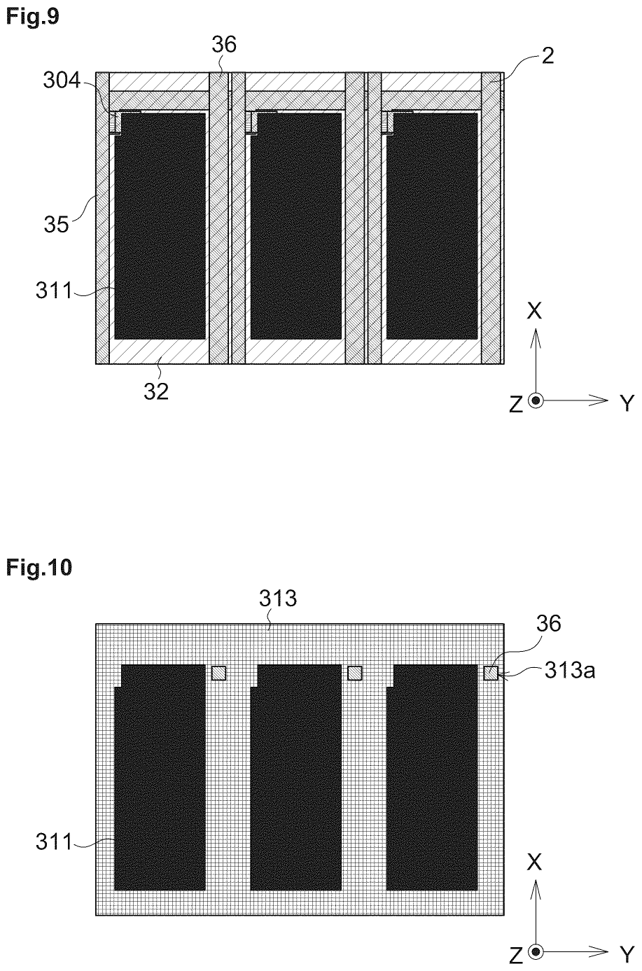

After the gate insulating layer 312 is formed, as shown in FIG. 10, a base layer 313 is formed. The base layer 313 is made of a dielectric material.

After the base layer 313 is formed, openings 313a are formed by removing the base layer 313 in areas located over the power source potential lines 36. The openings 313a are formed by subjecting the base layer 313 to exposure and development.

Then, contact holes 31a are formed in areas of the openings 313a. In this step, the contact holes 31a are formed by etching the one surface side of the substrate 2 using the base layer 313 having the openings 313a as a resist. At this time, the one surface side of the substrate 2 is etched until the power source potential lines 36 are exposed. As a result, areas of the gate insulating layer 312 and the protective layer 32 exposed by the openings 313a are removed so that the contact holes 31a are formed.

An etching method is not particularly limited as long as an adequate etching selectivity determined from the etching rate of the base layer 313 and the etching rate of the gate insulating layer 312 and the protective layer 32 is achieved. As such an etching method, either of plasma etching and wet etching may be used.

It is to be noted that instead of the above-described method in which patterning of the base layer 313, the gate insulating layer 312, and the protective layer 32 is performed by utilizing photosensitivity of the base layer 313, a method may also be used in which the base layer 313 is entirely cured by, for example, exposure or heating and then a photosensitive resist layer PR for patterning is separately formed on the base layer 313. In this case, when the photosensitive resist layer PR is of a negative type, the solubility of an exposed area in a developer is reduced. Therefore, a photomask M is formed so as to protect areas where the opening 313a are to be formed from light.

In the step of developing the photosensitive resist layer PR, the photosensitive resist layer PR is dipped in a developer. An exposed area is not dissolved in the developer, but areas protected from light in the exposure step are dissolved. Therefore, resist openings PRa are formed.

Then, openings 313a and contact holes 31a are formed in areas of the resist openings PRa. In this step, the openings 313a and the contact holes 31a are formed by etching the one surface side of the substrate 2 using the photosensitive resist layer PR having the resist openings PRa. At this time, the one surface side of the substrate 2 is etched until the power source potential lines 36 are exposed. As a result, areas of the base layer 313, the gate insulating layer 312, and the protective layer 32 exposed by the resist openings PRa are removed so that the contact holes 31a are formed.

It is to be noted that an etching method is not particularly limited and any etching method may be used as long as an adequate etching selectivity determined from the etching rate of the photosensitive resist layer PR and the etching rate of the base layer 313, the gate insulating layer 312, and the protective layer 32 is achieved. As such an etching method, either of plasma etching and wet etching may be used.

After the contact holes 31a are formed, the remaining photosensitive resist layer PR is removed (not shown). As described above, instead of utilizing the photosensitivity of the base layer 313, the photosensitive resist layer PR for patterning separately formed may be used to form the contact holes 31a.

After the contact holes 31a are formed in the etching step (or after the contact holes 31a are formed in the etching step and then the photosensitive resist layer PR is removed), a dispersion liquid containing a nano-carbon material (carbon material) is applied onto the base layer 313 formed on the main surface of the substrate 2, and therefore, as shown in FIG. 10, a pattern of a source electrode 314 is formed on the base layer 313 (corresponding to the step (C)).

In this step, the pattern is formed, on the base layer 313, by a coating film of the dispersion liquid containing a nano-carbon material using a printing technique such as casting, screen printing, or ink-jet printing. After the pattern is formed, a solvent is removed by drying so that the source electrode 314 is formed (corresponding to the step (D)).

When viewed from above, the pattern of the source electrode 314 is designed to be superposed on the openings 313a of the base layer 313. Therefore, the pattern of the source electrode 314 is connected to the power source potential lines 36 through the contact holes 31a shown in FIG. 10.

After the solvent is removed by drying, a cleaning fluid is applied onto the source electrode 314 formed on the main surface of the substrate 2 to remove a dispersant from the pattern formed by the coating film (corresponding to the step (E)). In this step, instead of the above-described method in which the pattern of the source electrode 314 is formed by printing, a method may also be used in which the dispersion liquid is once applied onto the entire surface of the base layer 313 formed on the main surface of the substrate 2, drying and cleaning are performed, and then a photosensitive resist layer PR for patterning is separately formed on the source electrode 314. In this case, after the photosensitive resist layer PR is formed, the electrically conductive layer is removed by etching, and the remaining photosensitive resist layer PR is removed (not shown).

It is to be noted that a combination of the dispersant and the cleaning fluid is not particularly limited, but the dispersant is preferably an alkali-soluble polymer having a functional group to improve solubility in an alkaline aqueous solution, and the cleaning fluid is preferably an alkaline aqueous solution. The use of an alkaline aqueous solution as the cleaning fluid makes it possible to allow the nano-carbon material less likely to be dispersed in the alkaline aqueous solution to selectively remain on the base layer 313. Further, the step using such an alkali-soluble polymer can share materials with the step using another photosensitive resist layer PR developed with an alkaline aqueous solution, which significantly enhances productivity. As the alkaline aqueous solution, for example, an aqueous KOH (potassium hydroxide) solution, an aqueous NaOH (sodium hydroxide) solution, an aqueous sodium carbonate solution, or an aqueous TMAH (tetramethylammonium hydroxide) solution can suitably be used.

The material of the dispersant may have a molecular structure that can improve solubility in an alkaline aqueous solution by causing decomposition or a structural change due to reaction to light or heat. The use of such a dispersant makes it possible to further improve the efficiency of removing the dispersant from the pattern formed by the coating film by exposing to light or applying heat to improve its solubility after formation of the source electrode 314 and before application of the cleaning fluid. The molecular structure having such a function may be, for example, a polyamic acid structure of the dispersant containing a moiety, such as cyclobutane, that is decomposed by light or heat so that the entire structure of a polyamic acid can be changed. The dispersant may contain an acid-dissociable group. The acid-dissociable group is a group that generates an acidic group such as a carboxyl group or a phenolic hydroxyl group due to the action of an acid. Examples of the acid-dissociable group include a group having a t-butoxy structure and a group having an acetal structure. The acid that acts on the acid-dissociable group is generated from an acid generating agent that generates an acid due to the action of light or heat. Therefore, the dispersion liquid contains an acid generating agent in addition to the dispersant having an acid-dissociable group.

Then, a bank 33 is formed. The material of the bank 33 is an insulating material. As the insulating material, an inorganic insulating material, an organic insulating material, or a combination thereof can be used. After a film is formed from the material of the bank 33, unnecessary portions are removed to form openings 33a.

Then, a light-emitting layer 315 is formed over the source electrode 314. In this step, the light-emitting layer 315 is formed at at least the openings 33a and the rims 33b and their vicinity of the bank 33 in pixel areas by vapor-depositing an organic material in a state where a metallic mask is placed over the substrate 2.

Then, a drain electrode 316 is formed over the light-emitting layer 315 so that the light-emitting transistors 31 of the present embodiment shown in FIG. 4 are completed. The material of the drain electrode 316 preferably contains a metallic material having a high reflectance. As such a metallic material having a high reflectance, for example, aluminum, silver, or the like can be used.

Although not shown, a protective layer may be formed over the drain electrode 316 so as to cover the entire surface of the substrate 2. As a material of the protective layer, an inorganic insulating material can be used. Examples of the inorganic insulating material include silicon nitride, silicon oxide, aluminum nitride, aluminum oxide, and a laminate of a combination of any two or more of these materials. It is to be noted that in order to make an electrical connection to an external terminal, the protective layer is removed in an area where the LSI chip 5 and the terminal part 6 are to be provided.

As is apparent from the above description, the light-emitting transistor 31 of the present embodiment includes the gate electrode 311, the gate insulating layer 312 provided over the gate electrode 311, the base layer 313 provided over the gate insulating layer 312 and having a dielectric property, the source electrode 314 provided in contact with the base layer 313 and containing a nano-carbon material, the light-emitting layer 315 provided over the source electrode 314, and the drain electrode 316 provided over the light-emitting layer 315.

In such a light-emitting transistor 31, the base layer 313 has the ability to adsorb a nano-carbon material, which improves adhesion between the base layer 313 and the source electrode 314. This enhances the processability of the source electrode 314 and resistance to a solvent during application of a photosensitive resist layer or resistance to a developer in a subsequent step, and further makes it easy to control a voltage applied to the gate electrode 311 to flow an electric current with a desired accuracy.

Further, the base layer 313 of the light-emitting transistor 31 has the opening 313a, and the source electrode 314 is connected through the opening 313a to the power source potential line 36 provided under the base layer 313. In such a light-emitting transistor 31, a desired voltage can be applied to the source electrode 314 through the power source potential line 36.

Further, in the light-emitting transistor 31, the base layer 313 has photosensitivity. In such a light-emitting transistor 31, the opening 313a can be formed by subjecting the base layer 313 to exposure and development. That is, the production process of the light-emitting transistor 31 can be simplified.

Further, in the light-emitting transistor 31, the nano-carbon material contains at least one of graphene and a carbon nanotube. In such a light-emitting transistor 31, adhesion between the base layer 313 and the source electrode 314 is further improved.

Further, in the light-emitting transistor 31, the nano-carbon material is a carbon nanotube, and the carbon nanotube is a single-wall carbon nanotube. In such a light-emitting transistor 31, adhesion between the base layer 313 and the source electrode 314 is further improved.

Further, in the light-emitting transistor 31, the base layer 313 can be formed from a radiation-sensitive composition for forming a base layer through steps that will be described below. The base layer 313 formed by such a formation method has unique electrical properties, excellent adhesiveness to carbon nanotubes, excellent chemical resistance, and excellent flatness. Further, in such a formation method, heating is performed at 140° C. or lower, which prevents thermal deterioration of the substrate and the devices provided on the substrate. Hereinbelow, each of the steps will be described in detail.

### [Step (1)]

In this step, a coating film is formed on the gate insulating layer 312 with the use of the radiation-sensitive composition. Specifically, a coating film of the radiation-sensitive composition is formed by applying the radiation-sensitive composition onto the surface of the gate insulating layer 312. It is to be noted that in this step, prebaking treatment is preferably performed to remove a solvent contained in the coating film.

Under the gate insulating layer 312, devices such as select transistors are provided. As described above, this formation method makes it possible to prevent deterioration of these devices caused by heating.

As an application method, for example, an appropriate method such as spray coating, roll coating, spin coating, slit die coating, bar coating, or ink-jet coating can be used. Among them, ink-jet coating is preferably used as the application method. The conditions of prebaking depend on, for example, the type and ratio of each component used, but may be, for example, 60° C. to 130° C. and about 30 seconds to 10 minutes. The thickness of the formed coating film after prebaking is preferably 0.1 μm to 5 μm, more preferably 0.1 μm to 1 μm, even more preferably 0.2 μm to 0.4 μm.

### [Step (2)]

In this step, part of the coating film is subjected to radiation irradiation (exposure). Specifically, the coating film formed in the step (1) is irradiated with radiation through a mask having a predetermined pattern. Depending on the pattern of the mask used, a pattern for forming contact holes, a pattern for forming lines and spaces, or the like can be formed. Examples of the radiation used at this time include ultraviolet, far ultraviolet, X-ray, and charged particle radiation. The mask used may be a multi tone mask such as a half tone mask or a gray tone mask.

Examples of the ultraviolet include g-ray (wavelength: 436 nm), i-ray (wavelength: 365 nm), and KrF excimer laser light (wavelength: 248 nm). Examples of the X-ray include synchrotron radiation and the like. Examples of the charged particle radiation include electron beams and the like. Among these radiations, ultraviolet is preferred, and ultraviolet having a wavelength of 200 nm or more and 380 nm or less is more preferred. The exposure amount of the radiation is preferably 1,000 J/m² to 20,000 J/m².

In some cases, post exposure baking (PEB) may be performed after exposure.

### [Step (3)]

In this step, the coating film that has been irradiated with radiation is developed. Specifically, the coating film irradiated with radiation in the step (2) is developed with a developer to remove a portion irradiated with radiation. As the developer, for example, an alkaline aqueous solution obtained by dissolving, in water, potassium hydroxide, sodium carbonate, triethanolamine, tetramethylammonium hydroxide (TMAH), or tetraethylammonium hydroxide or an organic solvent such as ethanol, isopropyl alcohol, acetone, ethyl acetate, or butyl acetate can be used.

As a development method, for example, an appropriate method such as a puddle method, a dipping method, a shake dipping method, or a showering method can be used. A developing time depends on the composition of the radiation-sensitive composition, but may be, for example, 30 seconds to 120 seconds.

### [Step (4)]

In this step, the coating film after the step (3) can be heated. The coating film is cured by heating treatment (post baking) with a heating apparatus such as a hot plate or an oven.

The upper limit of a heating temperature in this step is 140° C., and the heating temperature may be 130° C., 125° C., or 115° C. This formation method makes it possible for the coating film to have an excellent shape even by heating at such a relatively low temperature.

Further, in the light-emitting transistor 31, the source electrode 314 formed on the organic material layer can be formed from a composition containing a nano-carbon material through the following step.

As a method for applying the composition containing a nano-carbon material, for example, an appropriate method such as spray coating, roll coating, spin coating, slit die coating (slit coating), bar coating, solution dipping, or ink-jet coating can be used. A nano-carbon material layer is formed to have a certain thickness by a predetermined method. It is to be noted that in order to improve purity, the nano-carbon material layer is preferably subjected to a baking step to remove a solvent or a solution dipping step to remove a dispersant. Among the above-mentioned application methods, slit die coating or ink-jet coating is preferred from the viewpoints of thickness uniformity of a coating film and liquid saving. From the viewpoint that electrode patterning can be performed only by application, ink-jet coating is more preferred.

The use of this method for forming the base layer 313 makes it possible for the source electrode 314 formed on the upper side of the base layer 313 to have unique electrical properties, excellent adhesiveness to the base layer 313, excellent chemical resistance, and excellent flatness.

The display 1 of the present embodiment includes the substrate 2 and the pixels 3 arranged on one surface of the substrate 2, and each of the pixels 3 has any one of the above-described light-emitting transistors 31.

In such a display 1, the base layer 313 of the light-emitting transistor 31 has a dielectric property, which improves adhesion between the base layer 313 and the source electrode 314. This makes it easy to pass an electric current through the light-emitting transistor 31 with a desired accuracy when a voltage depending on a video signal is applied to the gate electrode 311. Therefore, it is not necessary to provide a compensation circuit or separately provide a transistor or a capacitor for each pixel 3 in order to pass an electric current through the light-emitting transistor 31 with a desired accuracy.

The method for producing the light-emitting transistor 31 of the present embodiment includes forming a gate electrode 311 on one surface side of a substrate 2, forming a gate insulating layer 312 on the one surface side after the formation of the gate electrode 311, forming a base layer 313 having a dielectric property on the one surface side after the formation of the gate insulating layer 312, forming a source electrode 314 containing a nano-carbon material on the base layer 313, forming a light-emitting layer 315 over the source electrode 314, and forming a drain electrode 316 over the light-emitting layer 315.

Such a method for producing the light-emitting transistor 31 makes it possible to produce the light-emitting transistor 31 in which the base layer 313 has a dielectric property and therefore achieves excellent adhesion to the source electrode 314. This improves production yield.

In the above-described production method, the base layer 313 has photosensitivity, power source potential lines 36 are formed on the one surface side before the gate insulating layer 312 is formed, the base layer 313 is subjected to exposure and development after the base layer 313 is formed to remove areas of the base layer 313 located over the power source potential lines 36, contact holes 31a are formed by etching the one surface side using the base layer 313 as a resist until the power source potential lines 36 are exposed, and the source electrode 314 connected to the power source potential lines 36 through the contact holes 31a is formed.

In such a method for producing the light-emitting transistor 31, the base layer 313 has photosensitivity and therefore functions as a resist. Therefore, the contact holes 31a can be formed without complicated steps such as resist application onto the base layer 313, exposure, development, etching, and resist removal. This simplifies the production process.

Further, in the above-described production method, the nano-carbon material contains at least one of graphene and a carbon nanotube. Such a method for producing the light-emitting transistor 31 makes it possible to produce the light-emitting transistor 31 in which adhesion between the base layer 313 and the source electrode 314 is more excellent. This further improves production yield.

Further, in the above-described production method, the nano-carbon material is a carbon nanotube, and the carbon nanotube is a single-wall carbon nanotube. Such a method for producing the light-emitting transistor 31 makes it possible to produce the light-emitting transistor 31 in which adhesion between the base layer 313 and the source electrode 314 is more excellent. This further improves production yield.

The method for producing the light-emitting transistor 31 of the present embodiment includes forming, on one surface of the substrate 2, a plurality of pixels 3 each containing the light-emitting transistor 31 formed by the above-described method.

Such a method for producing the light-emitting transistor 31 makes it possible to produce the light-emitting transistor 31 in which adhesion between the base layer 313 and the source electrode 314 is excellent because the base layer 313 of the light-emitting transistor 31 constituting the pixel 3 has a dielectric property. This improves production yield.

Further, in such a method for producing the light-emitting transistor 31, the base layer 313 has photosensitivity and therefore can function as a resist. Therefore, the contact holes 31a can be formed without complicated steps such as resist application onto the base layer 313, exposure, development, etching, and resist removal. This simplifies the production process.

### Verification and Evaluation Experiment

Finally, a verification and evaluation experiment will be described which was performed to determine how much effect the production method according to the present invention had on the dispersibility of carbon nanotubes as a nano-carbon material applied onto a substrate.

### 1. Synthesis of Polymers

### Synthesis Example 1: Synthesis of Polyamic Acid

A polyamic acid having a hydrocarbon group on a side chain (hereinafter referred to as a “polymer (paa-1)”) was obtained by a synthesis method described in Patent Document 2 mentioned above.

### Synthesis Example 2. Synthesis of Polyamic Acid

A photodegradable polyamic acid having a hydrocarbon group on a side chain (hereinafter referred to as a “polymer (paa-2)”) was obtained by a synthesis method described in Patent Document 3 mentioned above.

### Comparative Synthesis Example 1: Synthesis of Polyimide

N-methyl-2-pyrrolidone (NMP) was added to a polyamic acid solution obtained in the same manner as in Synthesis Example 1 described above. A predetermined imidization agent was added to the solution, and the mixture was subjected to reaction for a predetermined time by heating at 110° C. to obtain a polyimide (hereinafter referred to as a “polymer (PI-1)”). The obtained polymer (Pl-1) had an imidization ratio of 50%.

### 2. Preparation and Evaluation of CNT-Containing Dispersion Compositions

### (1) Preparation of Dispersion Compositions

First, 100,000 parts by mass of NMP was added as a solvent to a container containing 10 parts by mass of single-wall carbon nanotubes (SWNT) and 50 parts by mass of the polymer (paa-1) obtained in Synthesis Example 1 as a dispersant. Then, the mixture was subjected to ultrasonic dispersion for 60 minutes to prepare a dispersion composition (S-1).

Then, 100,000 parts by mass of NMP was added as a solvent to a container containing 10 parts by mass of single-wall carbon nanotubes (SWNT) and 100 parts by mass of the polymer (paa-1) obtained in Synthesis Example 1 as a dispersant. Then, the mixture was subjected to ultrasonic dispersion for 60 minutes to prepare a dispersion composition (S-2).

Then, 100.000 parts by mass of NMP was added as a solvent to a container containing 10 parts by mass of single-wall carbon nanotubes (SWNT) and 500 parts by mass of the polymer (paa-1) obtained in Synthesis Example 1 as a dispersant. Then, the mixture was subjected to ultrasonic dispersion for 60 minutes to prepare a dispersion composition (S-3).

Then, 100,000 parts by mass of NMP was added as a solvent to a container containing 10 parts by mass of single-wall carbon nanotubes (SWNT) and 1000 parts by mass of the polymer (paa-1) obtained in Synthesis Example 1 as a dispersant. Then, the mixture was subjected to ultrasonic dispersion for 60 minutes to prepare a dispersion composition (S-4).

Then, 100,000 parts by mass of NMP was added as a solvent to a container containing 10 parts by mass of single-wall carbon nanotubes (SWNT) and 5000 parts by mass of the polymer (paa-1) obtained in Synthesis Example 1 as a dispersant. Then, the mixture was subjected to ultrasonic dispersion for 60 minutes to prepare a dispersion composition (S-5).

Then, 100,000 parts by mass of NMP was added as a solvent to a container containing 10 parts by mass of single-wall carbon nanotubes (SWNT) and 500 parts by mass of the polymer (paa-2) obtained in Synthesis Example 2 as a dispersant. Then, the mixture was subjected to ultrasonic dispersion for 60 minutes to prepare a dispersion composition (S-6).

Then, 100,000 parts by mass of NMP was added as a solvent to a container containing 10 parts by mass of single-wall carbon nanotubes (SWNT) and 500 parts by mass of the polymer (PI-1) obtained in Comparative Synthesis Example 1 as a dispersant. Then, the mixture was subjected to ultrasonic dispersion for 60 minutes to prepare a dispersion composition (C-1).

### (2) Evaluation of CNT Dispersibility

The dispersion compositions (S-1) to (C-1) obtained in the above (1) were left to stand on a flat surface in an environment at 25° C. The CNT dispersibility of the dispersion compositions was evaluated according to the following criteria.
Most excellent (A): The dispersion composition kept its original dispersion state without settling of the CNTs even after 1 week.
Excellent (B): The dispersion composition kept its original dispersion state without settling of the CNTs for up to 3 days.
Good (C): The dispersion composition kept its original dispersion state without settling of the CNTs for up to 1 day.
Fair (D): The dispersion composition kept its original dispersion state without settling of the CNTs for up to 3 hours.
Poor (E): The CNTs settled or flocculated within 3 hours. As a result, the CNT dispersibility of the dispersion compositions (S-1) to (S-6) and (C-1) was evaluated as “Most excellent (A)”.

### (3) Evaluation of CNT Dispersion Stability (Durability)

Dispersion compositions were prepared in the same manner as in the above (1). The obtained dispersion compositions were left to stand on a flat surface in an environment at 40° C. to observe their dispersion state with time. The CNT dispersion stability of the dispersion compositions was evaluated according to the following criteria.
Most excellent (A): The dispersion composition kept its original dispersion state without settling of the CNTs even after 1 week.
Excellent (B): The dispersion composition kept its original dispersion state without settling of the CNTs for up to 3 days.
Good (C): The dispersion composition kept its original dispersion state without settling of the CNTs for up to 1 day.
Fair (D): The dispersion composition kept its original dispersion state without settling of the CNTs for up to 3 hours.
Poor (E): The CNTs settled or flocculated within 3 hours. As a result, the CNT dispersion stability of the dispersion compositions (S-1) to (S-6) and (C-1) was evaluated as “Most excellent (A)”.

### (4) Evaluation of CNT (Carbon Nanotube) Application Property

Each of the dispersion compositions (S-1) to (C-1) obtained in the above (1) was applied by spin coating onto a base layer 313 formed on a glass substrate and dried on a hot plate at 80° C. for 10 minutes to form a coating film whose thickness as measured in the center of the substrate was 0.1 μm. This coating film was observed under a microscope with 50 magnification to determine whether the coating film had thickness unevenness and a pinhole. The evaluation of the application property was made according to the following criteria.
Most excellent (A): Neither thickness unevenness nor a pinhole was observed.
Good (B): At least one of thickness unevenness and a pinhole was slightly observed. Poor (C): At least one of thickness unevenness and a pinhole was clearly observed. As a result, the application property of the dispersion compositions (S-3) to (S-5) and (C-1) was evaluated as “Most excellent (A)” because neither thickness unevenness nor a pinhole was observed. The application property of the dispersion compositions (S-1) and (S-2) was evaluated as “good (B)” because thickness unevenness was slightly observed.

### (5) Evaluation of Dispersant Removability

Each of the dispersion compositions (S-1) to (C-1) obtained in the above (1) was applied by spin coating onto a base layer 313 formed on a glass substrate and dried on a hot plate at 80° C. for 10 minutes to form a coating film whose thickness as measured in the center of the substrate was 0.1 μm. Further, in the case of (S-6), the coating film was irradiated with 1 J of ultraviolet having a wavelength of 260 nm with the use of a UV lamp. The coating film was dipped in an aqueous sodium hydroxide solution for 1 minute, and its surface was observed with an AFM (atomic force microscope, manufactured by Hitachi High-Tech Corporation).

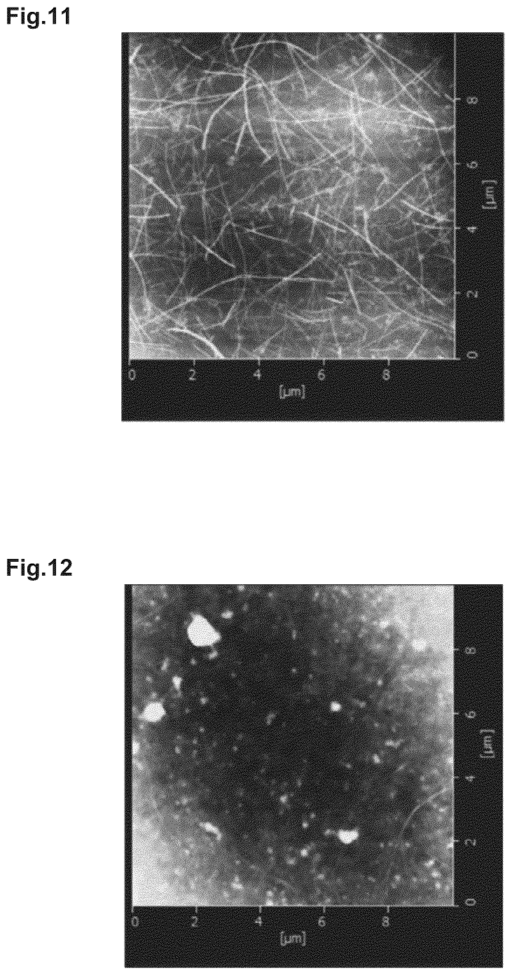

FIG. 11 and FIG. 12 are each an AFM photograph of the surface of the substrate. FIG. 11 is an example of a photograph of the surface of the substrate having irregularities caused by the CNTs, and FIG. 12 is an example of a photograph of the surface of the substrate where irregularities caused by the CNTs are not observed with an AFM, that is, the CNTs are covered with the resin-dispersant. The dispersant removability was evaluated according to the following criteria.
Good (A): The CNTs (carbon nanotubes) are exposed by removing the dispersant from the surface as shown in FIG. 11.
Fair (B): Some of the CNTs are exposed as shown in FIG. 12.
Poor (C): The surface is covered with the resin and therefore the CNTs are not exposed or evaluation cannot be made due to poor film formation.

As a result, the dispersion compositions (S-2) to (S-4) and (S-6) were evaluated as “Good (A)” because the dispersant was removed from the surface and therefore the CNTs (carbon nanotubes) were exposed. The dispersion composition (S-1) was evaluated as “Fair (B)” because the CNTs were exposed but flocculation of the CNTs was observed. The dispersion composition (S-5) was evaluated as “Fair (B)” because the CNTs were exposed but the surfaces of some of the CNTs were covered with the resin. The dispersion composition (C-1) was evaluated as “Poor (C)” because the surface was covered with the dispersant and therefore the CNTs were not exposed.

The above results are summarized below in Table 1.

TABLE 1

| | | CNT dispersant | CNT | CNT dispersion | CNT application | Dispersant | |
|---|---|---|---|---|---|---|---|
| | Dispersant | mass ratio | dispersibility | stability | property | removability | Decision |
| S-1 | paa-1 | 1:5 | A | A | B | B | OR |
| S-2 | paa-1 | 1:10 | A | A | B | A | OK |
| S-3 | paa-1 | 1:50 | A | A | A | A | OK |
| S-4 | paa-1 | 1:100 | A | A | A | A | OK |
| S-5 | paa-1 | 1:500 | 4 | A | A | B | OK |
| S-6 | paa-2 | 1:100 | A | A | A | A | OK |
| C-1 | PI-1 | 1:50 | A | A | A | C | NG |

What is claimed is:

1. A method for producing a vertical organic light-emitting transistor device, comprising:
a step (A) in which a substrate having a main surface, on which the vertical organic light-emitting transistor device is to be formed, is prepared;
a step (B) in which an organic material containing a polymer having a hydrocarbon group is applied onto the main surface of the substrate;
a step (C) in which a dispersion liquid containing a dispersant and a carbon material is applied onto an organic material layer formed in the step (B);
a step (D) in which a coating film formed in the step (C) is dried; and
a step (E) in which after the step (D) is performed, a cleaning fluid is applied to remove the dispersant.

2. The method for producing a vertical organic light-emitting transistor device according to claim 1, wherein the dispersion liquid contains the dispersant in an amount of 1,000% by mass to 100,000% by mass with respect to an amount of the carbon material.

3. The method for producing a vertical organic light-emitting transistor device according to claim 1, wherein the carbon material is at least one selected from among a carbon nanotube, graphene, and fullerene.

4. The method for producing a vertical organic light-emitting transistor device according to claim 3, wherein the carbon material is a carbon nanotube.

5. The method for producing a vertical organic light-emitting transistor device according to claim 1, wherein the dispersant is a polymer having a moiety represented by the following chemical formula (1), and the dispersion liquid is an organic solvent: 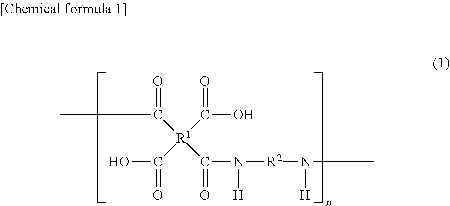
(wherein R¹ is a tetravalent organic group constituting a tetracarboxylic acid, R² is a divalent organic group constituting a diamine, and n is a positive integer).

6. The method for producing a vertical organic light-emitting transistor device according to claim 5, wherein in the moiety of the dispersant represented by the above chemical formula (1), R¹ is a cyclobutane ring.

7. The method for producing a vertical organic light-emitting transistor device according to claim 5, wherein the dispersant contains an acid-dissociable group.

8. The method for producing a vertical organic light-emitting transistor device according to claim 1, wherein an oxygen content of the organic material containing a polymer having a hydrocarbon group is 1% by mass or less.

9. The method for producing a vertical organic light-emitting transistor device according to claim 1, wherein in the step (C), the dispersion liquid is applied onto the organic material layer by any one of application methods including spin coating, slit coating, bar coating, spray coating, and ink-jet coating.

10. The method for producing a vertical organic light-emitting transistor device according to claim 1, wherein the cleaning fluid is an alkaline aqueous solution.

11. A display comprising a vertical organic light-emitting transistor device produced by the production method according to claim 1.

12. The method for producing a vertical organic light-emitting transistor device according to claim 2, wherein the carbon material is at least one selected from among a carbon nanotube, graphene, and fullerene.

13. The method for producing a vertical organic light-emitting transistor device according to claim 12, wherein the carbon material is a carbon nanotube.

14. The method for producing a vertical organic light-emitting transistor device according to claim 6, wherein the dispersant contains an acid-dissociable group.
